(19) United States
(12) Patent Application Publication
(10) Pub. No.: US 2018/0362806 A1
(43) Pub. Date: Dec. 20, 2018

(54) CHEMICAL MECHANICAL POLISHING SLURRY COMPOSITION AND METHOD OF FABRICATING SEMICONDUCTOR DEVICE USING THE SAME

(71) Applicants: Samsung Electronics Co., Ltd., Suwon-si (KR); K.C.TECH CO., LTD, Anseong-si (KR)

(72) Inventors: Seung Ho PARK, Suwon-si (KR); Chang Gil Kwon, Anseong-si (KR); Sung Pyo LEE, Anseong-si (KR); Jun Ha HWANG, Pyeongtaek-si (KR); Sang Kyun KIM, Hwaseong-si (KR); Hye Sung PARK, Siheung-si (KR); Su Young SHIN, Hwaseong-si (KR); Woo In LEE, Goyang-si (KR); Yang Hee LEE, Incheon (KR); Jong Hyuk PARK, Hwaseong-si (KR); Il Young YOON, Hwaseong-si (KR)

(21) Appl. No.: 15/822,117

(22) Filed: Nov. 25, 2017

(30) Foreign Application Priority Data
Jun. 16, 2017 (KR) 10-2017-0076462

(51) Int. Cl. C09G 1/02; H01L 21/3105

(52) U.S. Cl. CPC C09G 1/02; H01L 21/31055

(57) ABSTRACT

Provided are a chemical mechanical polishing (CMP) slurry composition and a method of fabricating a semiconductor device using the same. The chemical mechanical polishing (CMP) slurry composition includes abrasive particles, a first cationic compound which comprises at least any one of an amino acid, a polyalkylene glycol, a polymer polysaccharide to which a glucosamine compound is bonded, and a polymer containing an amine group, a second cationic compound which comprises an organic acid, and a nonionic compound which comprises polyetheramine.

This application claims the benefit of Korean Patent Application No. 10-2017-0076462, filed on Jun. 16, 2017, in the Korean Intellectual Property Office, the disclosure of which is incorporated herein in its entirety by reference.

### BACKGROUND

### 1. Technical Field

The present disclosure relates to a chemical mechanical polishing (CMP) slurry composition and a method of fabricating a semiconductor device using the same, and more particularly, to a CMP slurry composition including a polishing control agent and a method of fabricating a semiconductor device using the CMP slurry composition.

### 2. Description of the Related Art

As a film planarization process, an etch-back process, a reflow process, a chemical mechanical polishing (CMP) process, or the like can be used. The CMP process is widely used for wide-area planarization and highly integrated circuits because it is advantageous for wide-area planarization and has excellent flatness.

In the CMP process, an object to be polished may be mounted on a polishing device, and a slurry composition containing abrasive particles may be provided between the object and a polishing pad. In a state where the object is in contact with the polishing pad, the object may be rotated to planarize the surface of the object. For example, the CMP process is a process of mechanically polishing the surface of the object by mechanically rubbing the abrasive particles contained in the slurry composition and surface projections of the polishing pad against the surface of the object and, at the same time, is a process of chemically removing the surface of the object by chemically reacting the surface of the object with chemical components contained in the slurry composition.

It may be difficult for a CMP slurry composition having a relatively high selectivity and a relatively high removal rate to control flatness in an area having small steps, and the CMP slurry composition may cause dishing and scratching. Such problems may cause various defects in a semiconductor device manufactured using the CMP process which may adversely affect the yield and reliability of the semiconductor device.

### SUMMARY

Aspects of the present inventive concept provide a chemical mechanical polishing (CMP) slurry composition having a relatively high oxide film-to-semiconductor film polishing selectivity and capable of improving dishing and scratching.

Aspects of the present inventive concept also provide a method of fabricating a semiconductor device having improved reliability and yield.

However, aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

According to an aspect of the inventive concept, there is provided chemical mechanical polishing (CMP) slurry composition comprising abrasive particles, a first cationic compound which comprises at least any one of an amino acid, a polyalkylene glycol, a polymer polysaccharide to which a glucosamine compound is bonded, and a polymer containing an amine group, a second cationic compound which comprises an organic acid, and a nonionic compound which comprises polyetheramine.

According to another aspect of the inventive concept, there is provided a CMP slurry composition comprising, based on 100% by weight of the CMP slurry composition, 0.1% by weight to 10% by weight of abrasive particles, 0.001% by weight to 6% by weight of a cationic compound, and 0.001% by weight to 1% by weight of a nonionic compound which comprises polyetheramine.

According to another aspect of the inventive concept, there is provided a method of fabricating a semiconductor device, the method comprising providing a semiconductor pattern having a plurality of trenches, forming an insulating film on the semiconductor pattern to fill the plurality of trenches, and polishing the insulating film using a CMP slurry composition until an upper surface of the semiconductor pattern is exposed, wherein the CMP slurry composition comprises, based on 100% by weight of the CMP slurry composition, 0.1% by weight to 10% by weight of abrasive particles, 0.01% by weight to 10% by weight of a cationic compound, and 0.001% by weight to 1% by weight of a nonionic compound which comprises polyetheramine.

### BRIEF DESCRIPTION OF THE DRAWINGS

These and/or other aspects will become apparent and more readily appreciated from the following description of the embodiments, taken in conjunction with the accompanying drawings in which:

FIGS. 1 through 7 are views illustrating operations of a method of fabricating a semiconductor device according to embodiments of the inventive concept.

FIG. 8 is flow chart showing a method of manufacturing a semiconductor device according to exemplary embodiments of the inventive concept.

### DETAILED DESCRIPTION

Hereinafter, a chemical mechanical polishing (CMP) slurry composition according to embodiments of the present inventive concept will be described with reference to exemplary embodiments and drawings. However, the present inventive concept is not limited to these embodiments and drawings.

The CMP slurry composition according to the exemplary embodiments may include abrasive particles, a cationic compound, a nonionic compound, and a solvent.

The abrasive particles may function as an abrasive of the slurry composition. The abrasive particles may include a metal oxide. For example, the abrasive particles may include at least any one of a metal oxide, a metal oxide coated with an organic or inorganic material, and a metal oxide in a colloidal state.

In addition, the abrasive particles may include at least any one of silica, ceria, zirconia, alumina, titania, barium titania, germania, manganese dioxide, and magnesia.

The shape of the abrasive particles may be spherical, angular, needle-like, or plate-like. Preferably, the shape of the abrasive particles may be spherical.

The size of the abrasive particles, according to exemplary embodiments, may be 10 nm to 300 nm. When the size of the abrasive particles is less than 10 nm, a sufficient removal rate may not be ensured in a CMP process. When the size of the abrasive particles exceeds 300 nm, dishing and scratching may occur in the CMP process. In addition, it may be difficult to adjust the removal rate and the polishing selectivity.

The abrasive particles may include particles of a single size, but may also include particles of two or more sizes. For example, the size of the abrasive particles may be adjusted during a fabrication process, so that the abrasive particles can have a bimodal particle size distribution in which two types of particles are mixed Alternatively, the abrasive particles may have a particle size distribution in which three types of particles are mixed to show three peaks. Since, in some embodiments, relatively large abrasive particles are mixed with relatively small abrasive particles, better dispersibility can be obtained. Further, such abrasive particles can reduce scratches on a polishing target, improve dishing, and improve cleaning properties after polishing.

In some embodiments, the abrasive particles may have a positive charge on their surfaces. In a case where the surfaces of the abrasive particles are positively charged, the removal rate of an oxide film can be further improved.

The cationic compound may include a first cationic compound and a second cationic compound.

The first cationic compound may include at least any one of an amino acid, a polyalkylene glycol, a polymer polysaccharide to which a glucosamine compound is bonded, and a polymer containing an amine group.

The amino acid may include, for example, arginine.

The polymer polysaccharide to which the glucosamine compound is bonded may include a polymer polysaccharide to which a glucosamine compound of at least any one of chitin, chitosan, chitooligosaccharide, mucopolysaccharide, proteoglycan, heparin, alginic acid, cellulose, hyaluronic acid, carrageenan, β-glucan and chondroitin sulfate is bonded.

The polymer containing the amine group may include at least any one of, for example, a primary amine, a secondary amine, a tertiary amine, and a quaternary ammonium compound.

The second cationic compound may include an organic acid.

The organic acid may include at least any one of, for example, lactic acid, acetic acid, citric acid, malic acid, maleic acid, malonic acid, nitrilotriacetic acid, picolinic acid, nicotinic acid, isonicotinic acid, fusaric acid, dinicotinic acid, dipiconic acid, lutidinic acid, quinolic acid, glutamic acid, alanine, glycine, cystine, histidine, asparagine, guanidine, hydrazine, formic acid, acetic acid, benzoic acid, oxalic acid, succinic acid, tricarballyic acid, tartaric acid, aspartic acid, glutaric acid, adipic acid, suberic acid, fumaric acid, phthalic acid, and pyridine carboxylic acid.

The nonionic compound may include polyetheramine.

In some embodiments, the polyetheramine may be polyetheramine containing at least one of ethylene oxide and propylene oxide as a monomer. For example, the polyetheramine may be a compound formed by polymerization of ethylene oxide or propylene oxide.

In some embodiments, the polyetheramine may include 1 to 3 amine groups.

For example, the polyetheramine may include at least one of compounds represented by formulas (1) through (3) below.

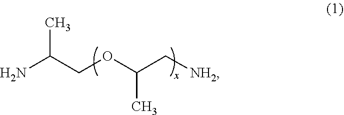

where x is a natural number of 2 to 10.

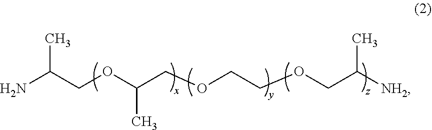

where x, y and z are each a natural number, the sum of x and z is 3 to 20, and y is 5 to 40.

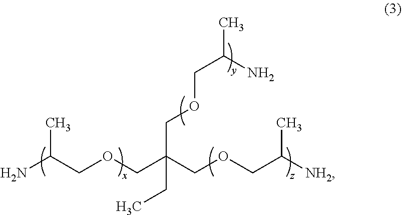

where x, y and z are each a natural number of 2 to 10.

The solvent may include deionized water. The solvent may also serve as a dispersion medium. For example, the solvent may serve as a solvent for a substance that is easily dissolved in a solvent, such as a first polishing control agent, but may serve as a dispersion medium for fine particles such as abrasive particles. For example, the solvent can serve as both a solvent and a dispersion medium, but will be referred to as a solvent herein for the sake of convenience.

The solvent may be included in the balance of the CMP slurry composition.

The CMP slurry composition according to the embodiments may further include an anionic compound.

The anionic compound may include at least any one of, for example, a copolymer in the form of a resonance structure functional group, a carboxyl group-containing polymer, and a carboxyl group-containing organic acid.

Part of the anionic compound may surround the surfaces of the abrasive particles. For example, when the surfaces of the abrasive particles are positively charged, part of the anionic compound may surround the surfaces of the abrasive particles through electrostatic bonding. In addition, part of the cationic compound may surround the anionic compound surrounding the surfaces of the abrasive particles. Accordingly, an abrasive particle composite having a positive charge on its surface can be formed. The abrasive particle composite can further improve the removal rate for the oxide film.

In the process of polishing an oxide film during the fabrication of a semiconductor device, a CMP slurry having a relatively high selectivity for the oxide film and having a relatively high removal rate of the oxide film can be used. However, it is difficult for the CMP slurry to control flatness in an area having small steps, and the CMP slurry causes dishing and scratching in the oxide film after polishing. Such problems can cause various defects such as a short circuit in a semiconductor device fabricated using the CMP process.

However, the CMP slurry composition according to the embodiments of the present inventive concept has a relatively high oxide film-to-semiconductor film polishing selectivity (a ratio of the removal rate of the oxide film to the removal rate of the semiconductor film) and a relatively high removal rate of the oxide film and can remarkably improve dishing and scratching.

Specifically, part of the cationic compound may be adsorbed onto the negatively charged surface of an oxide film, thereby protecting the surface of the oxide film from being excessively polished by the abrasive particles. For example, the surface of an oxide film containing SiO₂ may be negatively charged by oxygen atoms (O) having relatively high electronegativity. Part of the cationic compound may be electrostatically adsorbed onto the surface of the oxide film to protect the surface of the oxide film, thereby minimizing the occurrence of dishing and scratching.

In addition, the nonionic compound may be adsorbed onto a semiconductor film to protect the semiconductor film from the abrasive particles. For example, polyetheramine may be adsorbed by hydrophobic interactions with a semiconductor film containing SiGe to protect the semiconductor film from the abrasive particles. Accordingly, the polishing of the semiconductor film by the abrasive particles can be effectively suppressed, and the oxide film-to-semiconductor film polishing selectivity can be improved.

The CMP slurry composition according to the embodiments may include 0.1% by weight to 10% by weight of the abrasive particles, 0.001% by weight to 6% by weight of the cationic compound, and 0.001% by weight to 1% by weight of the nonionic compound based on 100% by weight of the CMP slurry composition.

When the content of the abrasive particles is less than 0.1% by weight, a sufficient removal rate may not be secured in the CMP process. When the content of the abrasive particles exceeds 10% by weight, dishing and scratching due to the CMP process may be excessive.

When the content of the cationic compound is less than 0.001% by weight, dishing and scratching of an oxide film to be polished may not be sufficiently improved. When the content of the abrasive particles exceeds 6% by weight, the dispersion stability of the CMP slurry composition may be degraded.

The content of the first cationic compound may be 0.01% by weight to 5% by weight based on 100% by weight of the CMP slurry composition. In addition, the content of the second cationic compound may be 0.001% by weight to 1% by weight based on 100% by weight of the CMP slurry composition.

When the content of the nonionic compound is less than 0.001% by weight, the oxide film-to-semiconductor film polishing selectivity may not be sufficiently high. When the content of the nonionic compound exceeds 1% by weight, a sufficient removal rate may not be secured, and excessive dishing and scratching may occur.

Hereinafter, the present inventive concept will be described in detail with reference to the following example and comparative examples. The following examples are merely illustrative of the inventive concept, and the present disclosure is not limited to these examples.

### EXAMPLE 1

A CMP slurry composition was prepared by mixing 5% by weight of ceria having a particle size of 100 nm as abrasive particles, 0.1% by weight of arginine as a first cationic compound, 0.07% by weight of acetic acid as a second cationic compound, and 0.01% by weight of 4,7,10-trioxamidecane-l 13-diamine (TTD) as a nonionic compound.

### Comparative Example 1

A CMP slurry composition was prepared in the same manner as in Example 1, except that the nonionic compound was not used.

### Comparative Example 2

A CMP slurry composition was prepared in the same manner as in Example 1, except that the first cationic compound and the second cationic compound were not used.

The content of the first cationic compound, the content of the second cationic compound, the content of the nonionic compound, the removal rate of the oxide film, the oxide film-to-semiconductor film polishing selectivity (the ratio of the rate of the oxide film removal to the rate of the semiconductor film removal), and the amount of dishing (the deviation in height of the oxide film) in Example 1, Comparative Example 1 and Comparative Example 2 are shown in Table 1 below.

TABLE 1

| | % by weight | | | | | |
|---|---|---|---|---|---|---|
| | First | Second | | Removal | | |
| | cationic | cationic | Nonionic | rate | Polishing | |
| | compound | compound | compound | (Å/min) | selectivity | Dishing (Å) |
| Example 1 | 0.1 | 0.07 | 0.01 | 4632 | 24:1 | 145 |
| Comparative | 0.1 | 0.07 | — | 4510 | 15:1 | 168 |
| Example 1 | | | | | | |
| Comparative | — | — | 0.01 | 4310 | 7:1 | 650 |
| Example 2 | | | | | | |

### Polishing Conditions

1. Polisher: AP-300 manufactured by CTS Corporation

2. Pad: K7 manufactured by Rohm & Hass Company

3. Polishing time: 60 seconds

4. Platen rpm: 87 rpm

5. Head rpm: 93 rpm

6. Flow rate: 300 ml/min

7. Polishing target: patterned wafer (SiGe of 3000 Å, SiO₂ of 6,500 to 6,700 Å)

Based on the above polishing conditions, the removal rate, the oxide film-to-semiconductor film polishing selectivity, and the amount of dishing were measured.

Referring to Table 1, comparing Example 1 and Comparative Example 1, it can be seen that the oxide film-to-semiconductor film polishing selectivity increases significantly in Example 1 using the nonionic compound. For example, when the content of the nonionic compound in the CMP slurry composition is 0.1% by weight, the oxide film-to-semiconductor film polishing selectivity is increased by about 60% compared to when the CMP slurry composition contains no nonionic compound.

In addition, comparing Example 1 and Comparative Example 2, it can be seen that the amount of dishing is reduced significantly in Example 1 using the cationic compound. For example, when the content of the first cationic compound in the CMP slurry composition is 0.1% by weight and the content of the second cationic compound in the CMP slurry composition is 0.07% by weight, the amount of dishing is reduced by about 75% or more compared to when the CMP slurry composition contains no cationic compounds.

The present inventive concept will now be described in more detail with reference to the following example and comparative examples. The following examples are merely illustrative of the inventive concept, and the present disclosure is not limited to these examples.

### EXAMPLE 2

A CMP slurry composition was prepared in the same manner as in Example 1, except that the content of the nonionic compound was changed to 0.03% by weight.

### Comparative Example 3

A CMP slurry composition was prepared in the same manner as in Example 1, except that the content of the nonionic compound was changed to 0.0005% by weight.

### Comparative Example 4

A CMP slurry composition was prepared in the same manner as in Example 1, except that the content of the nonionic compound was changed to 1.2% by weight.

The content of the nonionic compound, the removal rate, the oxide film-to-semiconductor film polishing selectivity, and the amount of dishing in Example 1, Example 2, Comparative Example 3 and Comparative Example 4 are shown in Table 2 below.

TABLE 2

| | Nonionic | | | |
|---|---|---|---|---|
| | compound | Removal | | |
| | (% by | rate | Polishing | Dishing |
| | weight) | (Å/min) | selectivity | (Å) |
| Example 1 | 0.01 | 4632 | 24:1 | 145 |
| Example 2 | 0.03 | 4703 | 25:1 | 142 |
| Comparative | 0.0005 | 4570 | 15:1 | 164 |
| example 3 | | | | |
| Comparative | 1.2 | 2850 | 10:1 | 680 |
| example 4 | | | | |

Referring to table 2, Example 1 and Example 2 have a relatively high removal rate of 4000 Å/ min or more, a relatively high oxide film-to-semiconductor film polishing selectivity of 20:1 or more, and a low dishing amount of 200 Å or less.

Specifically, comparing Example 1, Example 2, and Comparative Example 3, it can be seen that the oxide-to-semiconductor film polishing selectivity significantly increases when the content of the nonionic compound is 0.001% by weight or more. For example, when the content of the nonionic compound in the CMP slurry composition is about 0.01% by weight or more, the oxide film-to-semiconductor film polishing selectivity is increased by about 60% or more compared to when the content of the nonionic compound in the CMP slurry composition is about 0.0005% or less.

In addition, comparing Example 1, Example 2, and Comparative Example 4, it can be seen that, when the content of the nonionic compound is 1% by weight or less, the removal rate increases remarkably and the amount of dishing decreases significantly. For example, when the content of the nonionic compound in the CMP slurry composition is about 0.01% by weight but less than 1% by weight, the amount of dishing is reduced by about 75% or more compared to when the content of the nonionic compound in the CMP slurry composition is more than 1% by weight. In addition, when the content of the nonionic compound in the CMP slurry composition is about 0.01% by weight but less than 1% by weight, the removal rate is increased by about 35% or more compared to when the content of the nonionic compound in the CMP slurry composition is more than 1% by weight.

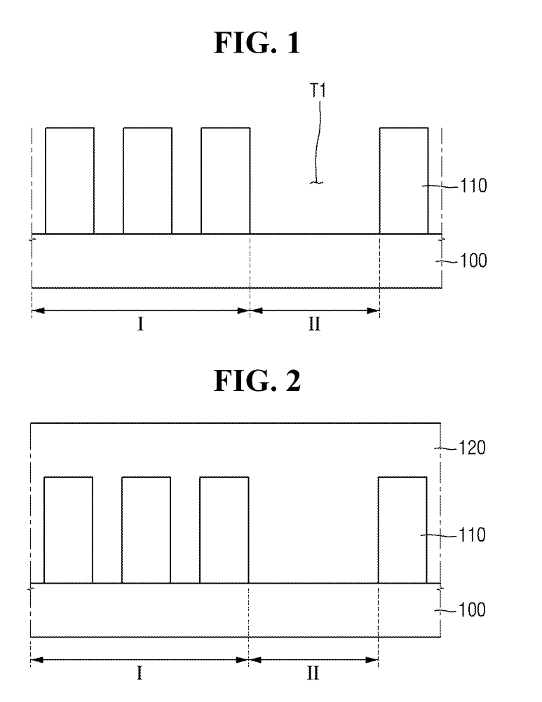

Hereinafter, a method of fabricating a semiconductor device according to embodiments of the present inventive concept will be described with reference to FIGS. 1 through 7. As used herein, a semiconductor device may refer to a device such as a semiconductor chip (e.g., memory chip and/or logic chip formed on a die cut from a semiconductor wafer).

FIGS. 1 through 7 are views illustrating operations of a method of fabricating a semiconductor device according to exemplary embodiments of the inventive concept.

Referring to FIG. 1, a semiconductor pattern 110 is provided. For example, the semiconductor pattern 110 including a plurality of trenches T1 may be provided on a substrate 100. The substrate 100 may be a semiconductor crystalline material (e.g., a crystalline silicon wafer or crystalline SiGe wafer).

The substrate 100 may include a first area I and a second area II. The first area I may be, for example, a memory cell area in which a nonvolatile memory is formed. In addition, the second area II may be a peripheral circuit area in which, for example, circuit elements necessary for operation of the memory cell area are disposed.

The semiconductor pattern 110 may be formed on the first area I of the substrate 100. The semiconductor pattern 110 may be a multilayer structure including a transistor or a conductive wiring layer, The semiconductor pattern 110 may include an insulating material liner which electrically insulates a semiconductor material or a conductive material or covers the semiconductor material or the conductive material. However, the present disclosure is not limited to this case, and the semiconductor pattern 110 can have various structures depending on a required semiconductor device.

The semiconductor pattern 110 may include a semiconductor film. For example, the semiconductor pattern 110 may include a silicon germanium film. However, the semiconductor pattern 110 can also include another semiconductor film such as a silicon film or a gallium arsenide film. The semiconductor pattern 110 may include, for example, silicon nitride (SiN). The semiconductor pattern 110 may be a semiconductor film formed on a substrate (e.g., by epitaxially growing a crystalline semiconductor pattern from a surface of the substrate 100) or the semiconductor pattern 110 may be formed by patterning the surface of the semiconductor substrate 100 (and thus is integral and homogenous with the remainder of the substrate 100).

Referring to FIGS. 1 and 2, a first insulating film 120 is formed on the semiconductor pattern 110. The first insulating film 120 may be formed to fill the trenches T1 in the semiconductor pattern 110. Accordingly, portions of the semiconductor pattern 110 may be separated by the first insulating film 120.

The first insulating film 120 may be formed by, but not limited to, a chemical vapor deposition (CVD) process.

The first insulating film 120 may include an oxide film. The first insulating film 120 may be formed of at least one of a silicon oxide (SiO₂) film, a high density plasma (HDP) film, an undoped silicate glass (USG) film, a silicon oxide fluoride (SiOF) film, a spin on glass (SOG) film, a silicon rich oxide (SROX) film, films formed from using tetraethyl orthosilicate (TEOS) as a precursor (e.g., SiO₂), films formed from using a plasma enhanced tetraethyl orthosilicate (PETEOS) (e.g., an SiO₂ film), a phosphorus silicate glass (PSG) film, a born-phosphorus silicate glass (BPSG) film, and combinations of these films.

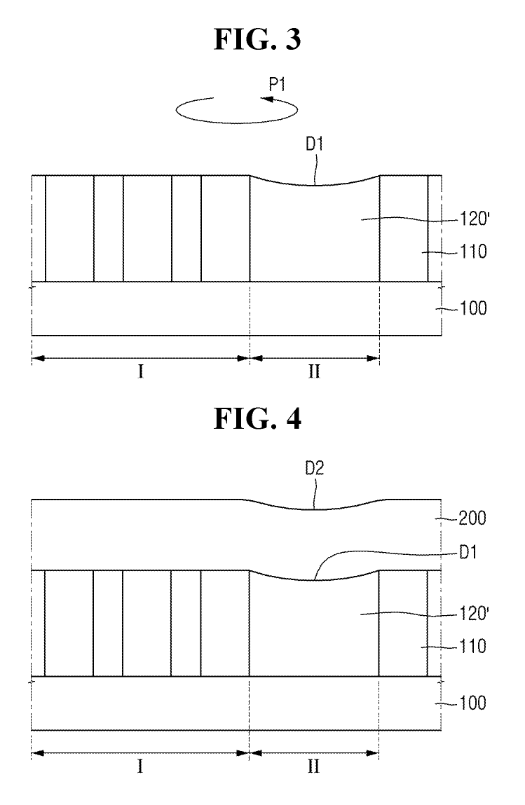

Referring to FIG. 3, an upper surface of the first insulating film 120 is planarized using a first CMP process P1 until an upper surface of the semiconductor pattern 110 is exposed. Accordingly, a first insulating film pattern 120′ may be formed.

Due to the first CMP process P1, an upper surface of the first insulating film pattern 120′ may include dishing. Such dishing may be exacerbated as the gap between the portions of the semiconductor pattern 110 increases, For example, as illustrated, first dishing D1 may be formed in the first insulating film pattern 120′ formed on the second area II.

The first CMP process P1 uses a CMP slurry composition according to embodiments of the inventive concept. For example, the first CMP process P1 may use a CMP slurry composition including a first cationic compound which includes at least any one of an amino acid, a polyalkylene glycol, a polymer polysaccharide to which a glucosamine compound is bonded and a polymer containing an amine group, a second cationic compound which includes an organic acid, and a nonionic compound which includes polyetheramine.

Accordingly, the first CMP process P1 can secure a relatively high removal rate, thereby improving the productivity of the semiconductor device fabrication process. In addition, since the first CMP process P1 has a relatively high oxide film-to-semiconductor film polishing selectivity and a small amount of dishing, the flatness of the first insulating film pattern 120′ can be improved. For example, the first CMP process P1 can minimize the occurrence of the first dishing D1.

Referring to FIG. 4, a second insulating film 200 is formed on the semiconductor pattern 110 and the first insulating film pattern 120′.

The second insulating film 200 may include second dishing D2. Since the second insulating film 200 is formed on the first insulating film pattern 120′, the second dishing D2 may be formed on the first dishing D1. However, since the method of fabricating a semiconductor device according to the embodiments uses the first CMP process P1, the occurrence of the second dishing D2 can be minimized by minimizing the occurrence of the first dishing D1. In some embodiments, the second dishing D2 may not occur.

The second insulating film 200 may be formed by, but not limited to, the CVD process.

The second insulating film 200 may include at least one of, for example, silicon oxide, silicon nitride, and silicon oxynitride.

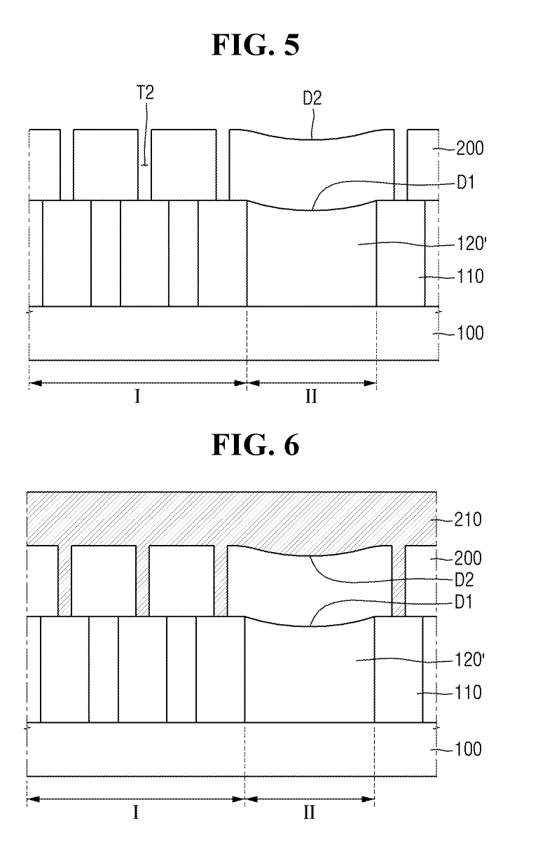

Referring to FIG. 5, a plurality of contact holes T2 are formed in the second insulating film 200.

For example, a dry etching process may be used to form each of the contact holes T2. Specifically, a mask pattern may be formed on the second insulating film 200. The mask pattern may expose an area where each contact hole T2 is to be formed. Then, the contact holes T2 may be formed in the second insulating film 200 by etching the areas exposed by the mask pattern.

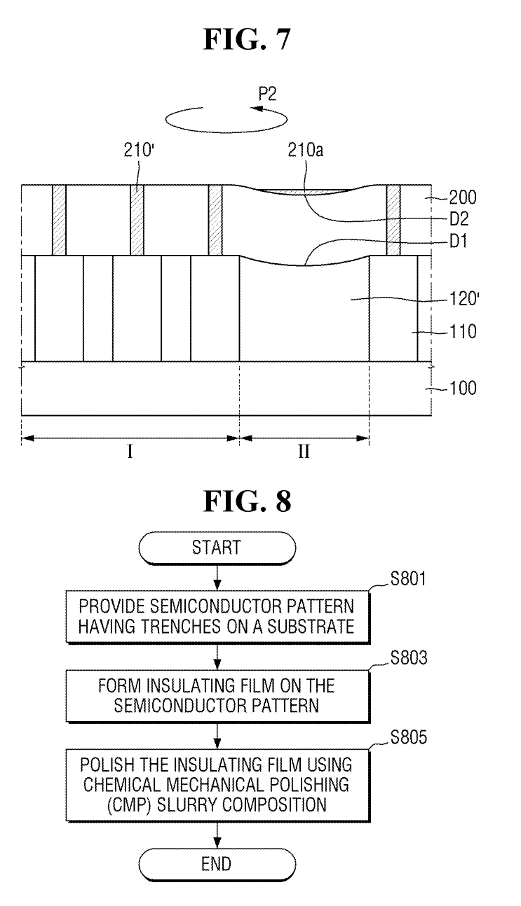

Each contact hole T2 is designed to provide a space in which a conductive film pattern 210′ (see FIG. 7) to be described later is to be formed. Accordingly, each contact hole T2 can have various shapes depending on the required conductive film pattern 210′. For example, each contact hole T2 may have a line shape or a hole shape. For example, the contact holes T2 may be formed to penetrate the second insulating film 200 and expose at least part of the semiconductor pattern 110.

Referring to FIG. 6, a conductive film 210 is formed on the semiconductor pattern 110 and the second insulating film 200.

The conductive film 210 may be formed by, but not limited to, the CVD process, a plating process, or a physical vapor deposition (PVD) process. The conductive film 210 may be formed to fill the contact holes T2. Accordingly, the conductive film 210 may contact the semiconductor pattern 110.

The conductive film 210 may include at least one of, for example, aluminum (Al), copper (Cu), tungsten (W), titanium (Ti), cobalt (Co), and combinations of these materials.

Referring to FIGS. 6 and 7, an upper surface of the conductive film 210 is planarized using a second CMP process P2 until an upper surface of the second insulating film 200 is exposed. Accordingly, the conductive film patterns 210′ separated by the second insulating film 200 may be formed.

Here, a conductive residue 210a may remain on the second dishing D2. The conductive residue 210a may be a portion of the conductive film 210 which has not been polished in the second CMP process P2 due to the second dishing D2.

If the first CMP process P1 is not performed, the first dishing D1 may occur excessively, resulting in the excessive formation of the conductive residue 210a. The conductive residue 210a may hinder the conductive film patterns 210′ from being completely separated by the second insulating film 200. As a result, a defect such as a short circuit may occur in a manufactured semiconductor device, thus reducing the reliability and yield of the semiconductor device.

However, since the method of fabricating a semiconductor device according to the exemplary embodiments uses the first CMP process P1, the formation of the conductive residue 210a can be minimized by minimizing the occurrence of the first dishing D1. In some embodiments, the conductive residue 210a may not be formed at all. Accordingly, the method of fabricating a semiconductor device according to the exemplary embodiments can improve the reliability and the yield of a semiconductor device.

FIG. 8 is flow chart showing a method of manufacturing semiconductor device according to exemplary embodiments of the inventive concept.

In step S801, a semiconductor pattern having a plurality of trenches is provided on a substrate, e.g., a semiconductor wafer W. The semiconductor pattern may be a semiconductor pattern 110 and the substrate may be a substrate 100 according to the exemplary embodiments as disclosed above. The substrate 100 may include a first area I and a second area II. The first area I may be, for example, a memory cell area in which a nonvolatile memory is formed. In addition, the second area II may be a peripheral circuit area in which, for example, circuit elements necessary for operation of the memory cell area are disposed. The semiconductor pattern 110 having a plurality of trenches T1 may be formed on the first area I of the substrate 100.

In step S803, an insulating film may be formed on the semiconductor pattern 110. The insulating film may be a first insulating film 120 according to the exemplary embodiments as disclosed above. The first insulating film 120 may fill the plurality of trenches T1.

In step S805, the first insulating film 120 may be polished using a CMP slurry composition until an upper surface of the semiconductor pattern 110 is exposed. The CMP slurry composition may be a CMP slurry composition according to the exemplary embodiments as disclosed above. For example, the CMP slurry composition may comprise, based on 100% by weight of the CMP slurry composition, 0.1% by weight to 10% by weight of abrasive particles, 0.01% by weight to 10% by weight of a cationic compound, and 0.001% by weight to 1% by weight of a nonionic compound which may comprise polyetheramine. Semiconductor chips (having integrated circuits formed therein) may be cut from the wafer W and form elements of semiconductor device packages.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A chemical mechanical polishing (CMP) slurry composition comprising:
abrasive particles;
a first cationic compound which comprises at least any one of an amino acid, a polyalkylene glycol, a polymer polysaccharide to which a glucosamine compound is bonded, and a polymer containing an amine group;
a second cationic compound which comprises an organic acid; and
a nonionic compound which comprises polyetheramine.

2. The CMP slurry composition of claim 1, wherein surfaces of the abrasive particles are positively charged.

3. The CMP slurry composition of claim 1, wherein content of the abrasive particles is 0.1% by weight to 10% by weight based on 100% by weight of the CMP slurry composition.

4. The CMP slurry composition of claim 1, wherein content of the first cationic compound is 0.01% by weight to 5% by weight based on 100% by weight of the CMP slurry composition.

5. The CMP slurry composition of claim 1, wherein the organic acid comprises at least any one of lactic acid, acetic acid, citric acid, malic acid, maleic acid, malonic acid, nitrilotriacetic acid, picolinic acid, nicotinic acid, isonicotinic acid, fusaric acid, dinicotinic acid, dipiconic acid, lutidinic acid, quinolic acid, glutamic acid, alanine, glycine, cystine, histidine, asparagine, guanidine, hydrazine, formic acid, acetic acid, benzoic acid, oxalic acid, succinic acid, tricarballyic acid, tartaric acid, aspartic acid, glutaric acid, adipic acid, suberic acid, fumaric acid, phthalic acid, and pyridine carboxylic acid.

6. The CMP slurry composition of claim 1, wherein content of the second cationic compound is 0.001% by weight to 1% by weight based on 100% by weight of the CMP slurry composition.

7. The CMP slurry composition of claim 1, wherein content of the nonionic compound is 0.001% by weight to 1% by weight based on 100% by weight of the CMP slurry composition.

8. The CMP slurry composition of claim 1, wherein the polyetheramine comprises at least one of ethylene oxide and propylene oxide as a monomer.

9. The CMP slurray composition of claim 1, wherein the polyetheramine comprises 1 to 3 amine groups.

10. The CMP slurry composition of claim 1, wherein the polyetheramine comprises at least one of compounds represented by formulas (1) through (3):

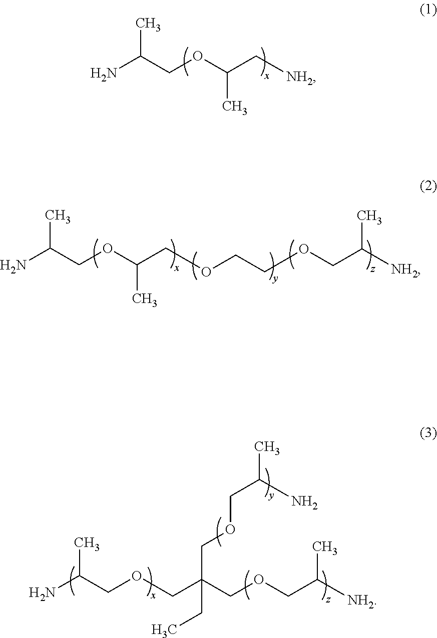

11. The CMP slurry composition of claim 1, further comprising an anionic compound which comprises at least any one of a copolymer in a form of a resonance structure functional group, a carboxyl group-containing polymer, and a carboxyl group-containing organic acid.

12. A CMP slurry composition comprising, based on 100% by weight of the CMP slurry composition:
0.1% by weight to 10% by weight of abrasive particles;
0.001% by weight to 6% by weight of a cationic compound; and
0.001% by weight to 1% by weight of a nonionic compound which comprises polyetheramine.

13. The CMP slurry composition of claim 12, wherein surfaces of the abrasive particles are positively charged.

14. The CMP slurry composition of claim 12, wherein the cationic compound comprises:
a first cationic compound which comprises at least any one of an amino acid, a polyalkylene glycol, a polymer polysaccharide to which a glucosamine compound is bonded, and a polymer containing an amine group; and
a second cationic compound which comprises an organic acid.

15. The CMP slurry composition of claim 14, wherein content of the first cationic compound is 0.01% by weight to 5% by weight based on 100% by weight of the CMP slurry composition, and content of the second cationic compound is 0.001% by weight to 1% by weight based on 100% by weight of the CMP slurry composition.

16. The CMP slurry composition of claim 14, wherein the organic acid comprises at least any one of lactic acid, acetic acid, citric acid, malic acid, maleic acid, malonic acid, nitrilotriacetic acid, picolinic acid, nicotinic acid, isonicotinic acid, fusaric acid, dinicotinic acid, dipiconic acid, lutidinic acid, quinolic acid, glutamic acid, alanine, glycine, cystine, histidine, asparagine, guanidine, hydrazine, formic acid, acetic acid, benzoic acid, oxalic acid, succinic acid, tricarballyic acid, tartaric acid, aspartic acid, glutaric acid, adipic acid, suberic acid, fumaric acid, phthalic acid, and pyridine carboxylic acid.

17. The CMP slurry composition of claim 12, wherein the polyethera comprises at least one of ethylene oxide and propylene oxide as a monomer.

18. The CMP slurry composition of claim 12, wherein the polyetheramine comprises 1 to 3 amine groups.

19. A method of fabricating a semiconductor device, the method comprising:
providing a semiconductor pattern having a plurality of trenches;
forming an insulating film on the semiconductor pattern to fill the plurality of trenches; and
polishing the insulating film using a CMP slurry composition until an upper surface of the semiconductor pattern is exposed,
wherein the CMP slurry composition comprises, based on 100% by weight of the CMP slurry composition, 0.1% by weight to 10% by weight of abrasive particles, 0.01% by weight to 10% by weight of a cationic compound, and 0.001% by weight to 1% by weight of a nonionic compound which comprises polyetheramine.

20. The method of claim 19, wherein the insulating film comprises at least one of a silicon oxide (SiO₂) film, a high density plasma (HDP) film, an undoped silicate glass (USG) film, a silicon oxide fluoride (SiOF) film, a spin on glass (SOG) film, a silicon rich oxide (SROX) film, a tetraethyl orthosilicate (TEOS) film, a plasma enhanced tetraethyl orthosilicate (PETEOS) film, a phosphorus silicate glass (PSG) film, a boro-phosphorus silicate glass (BPSG) film, and combinations of these films.
